(19) United States
(12) Patent Application Publication
(10) Pub. No.: US 2008/0253925 A1
(43) Pub. Date: Oct. 16, 2008

(54) TARGET MATERIAL FOR ELECTRODE FILM, METHODS OF MANUFACTURING THE TARGET MATERIAL AND ELECTRODE FILM

(75) Inventors: Jianshe XUE, Beijing (CN); Ke LIANG, Beijing (CN)

Correspondence Address: SHERIDAN ROSS PC, 1560 BROADWAY, SUITE 1200, DENVER, CO, 80202, US

(73) Assignee: BEIJING BOE OPTOELECTRONICS TECHNOLOGY CO., LTD, Beijing (CN)

(21) Appl. No.: 11/957,880

(22) Filed: Dec. 17, 2007

(30) Foreign Application Priority Data
Apr. 11, 2007 (CN) 200710065345.5

(51) Int. Cl. C22C 21/00; B22D 23/00; B22D 29/00; B05D 5/12; C21D 1/26; C23C 14/34

(52) U.S. Cl. 420/550; 164/46; 164/131; 427/123; 148/537; 204/192.17; 420/528

(57) ABSTRACT

Provided are a target material for manufacturing an electrode film of a semiconductor device, methods of manufacturing the target material and manufacturing the electrode film. The target material comprises Al-RE alloy or Al—Ni-RE alloy, in which RE is a mixture of rare earth elements comprising La, Ce, Pr, and Nd.

### BACKGROUND OF THE INVENTION

The present invention relates to a target material for manufacturing electrodes of a semiconductor device, a method of manufacturing the target material, and a method of manufacturing an electrode with the target material. In particular, the present invention relates to a target material for manufacturing the electrode film of a thin-film transistor liquid crystal display (TFT LCD), a method of manufacturing the target material, and a method of manufacturing an electrode with the target material.

At present, as the thin-film transistor liquid crystal display is being developed toward that of large scale and high resolution, metal electrode film with very low electrical resistivity is required for the gate, source and drain electrode of a TFT. For a TFT LCD of over 10 inches, for example, the electrical resistivity of an electrode has to be smaller than 20 μΩcm. At the same time, in the manufacturing of a large scale integrated circuit, a substrate may not provide sufficient landing area for depositing the interconnection wire necessary for an IC. Thus, multilayered metal interconnection wire becomes necessary to manufacture an IC. Four to five metal layers are generally required to carry out the interconnection between ICs, especially for an IC with complicated functions such as a microprocessor. Thus, gold (Au), copper (Cu), and aluminum (Al) are preferred metals for the electrodes or interconnection wires of an IC or TFTs. However, Au is prevented from being widely used by its poor adhering ability with a substrate and poor etching property as well as expensiveness. Cu is also prevented from being used by its poor adhering ability with a substrate and poor corrosion resistance. Al possesses not only good electrical resistivity but also excellent etching property and adhering ability with a substrate. Furthermore, Al is of a large reserve in the earth and can be obtained easily and thus has been widely used.

However, Al has a large disadvantage of insufficient thermal stability. Such thermal instability brings about the problem that very small protrusions (or “hillocks”) will appear on the surface of the metallic electrode film made of Al during subsequent heat treatment. The electrode film is typically used as an underlying layer, and the size of the hillock becomes very large with respect to the width of the electrode or the interconnection wire if the width of the wire is formed fine after being patterned by etching. As a result, if another insulation film is deposited thereon, the hillock may penetrate the insulating film above it and cause a short circuit. In other cases, an open circuit may be caused in a place where the hillock is formed.

There are two approaches currently adopted for suppressing formation of hillocks on the surface of an Al film. One approach is to form a film of a metal having very high melting point, such as a film of a refractory metal, on the Al layer. The second approach is to add other elements in Al to obtain an alloy and use this alloy to form the electrode film. Presently, in forming of the electrode of a TFT, the most widely used approach is to form a conductive film with AlNd alloy and interpose the layer with an underlying layer and an overlying layer made of Mo. However, due to the fact that the alloying element Nd is a mixture of rare earth elements element, the reserve of which is very small in the earth, and is difficult to purify, and therefore the cost of AlNd is quite high. Therefore, it becomes necessary to find another suitable Al alloy to substitute for AlNd.

### SUMMARY OF THE INVENTION

The present invention is made in consideration of the problem in the related art that AlNd alloy is expensive and purification of Nd is difficult. In the embodiments of the present invention, it is to substitute a mixture of rare earth elements RE (RE=La, Ce, Pr, Nd), from which Nd is purified, for Nd in a target material, so as to obtain the target material at a reduced cost. Also, metal Ni can be added into the target material to improve resistance to corrosion and oxidation of the target material. That is, a suitable alloy of Al-RE or Al—Ni-RE is provided instead of AlNd alloy to form a target material, and an electrode film that is used in a semiconductor device can be manufactured with such a target material. The present invention also is to provide a method of manufacturing an electrode film.

According to one aspect of the present invention, a target material for manufacturing an electrode film of a semiconductor device is provided. The target material comprises Al-RE alloy or Al—Ni-RE alloy, where RE is a mixture of rare earth elements comprising La, Ce, Pr, and Nd.

Preferably, the content of RE in Al-RE alloy or of Ni and RE in Al—Ni-RE alloy may be in a range of about 0.1 wt % to about 20 wt %.

According to another aspect of the present invention, a method of manufacturing a target material for an electrode film of a semiconductor device is provided. In the method, a rotating substrate is provided first. Then, a material which comprises Al and RE is molten, where RE is a mixture of rare earth elements comprising La, Ce, Pr, and Nd. The molten material is atomized into droplets by ejecting working gas with an atomizing nozzle, and the droplets are brought with a flow of the working gas to the rotating substrate, so as to form a blank on a surface of the rotating substrate. The blank then is reshaped and densified. At last, the blank is formed into a final dimension.

Preferably, the material may comprise powders of Al and RE. Alternatively, the material may comprise Al-RE alloy.

Preferably, the material may further comprise Ni, and the material may comprise powders of Al, Ni and RE. Alternatively, the material may comprise Al—Ni-RE alloy.

According to still another aspect of the present invention, a method of manufacturing a target material for an electrode film of a semiconductor device is provided. In the method, a material which comprises Al and RE is molten, where RE is a mixture of rare earth elements comprising La, Ce, Pr, and Nd. The molten material is poured into a preheated mold cavity, so as to obtain a blank after the material is cooled. The blank is taken out of the mold cavity. At last, the blank is formed into a final dimension.

Preferably, the material may comprise powders of Al and RE. Alternatively, the material may comprise Al-RE alloy.

Preferably, the material may further comprise Ni. The material may comprise powders of Al, Ni and RE. Alternatively, the material may comprise Al—Ni-RE alloy.

Preferably, the blank may be forged before it is formed into the final dimension.

According to a further aspect of the present invention, a method of manufacturing an electrode film of a semiconductor device is provided. The method comprises the step of depositing an electrode film on a substrate with a target material comprising Al-RE alloy or Al—Ni-RE alloy, where RE is a mixture of rare earth elements comprising La, Ce, Pr, and Nd.

Preferably, in the method, a refractory metal layer may be deposited on the substrate before depositing the electrode film on the substrate with a target material comprising Al-RE alloy or Al—Ni-RE alloy, and then the layer of Al-RE or Al—Ni-RE is deposited as a conductive layer with a target material comprising Al-RE alloy or Al—Ni-RE alloy, so that an electrode film of a two-layered structure is formed. Alternatively, another refractory metal layer may be deposited on the conductive film layer after forming the two-layered electrode film, to form a three-layered structure.

Preferably, the electrode film may be deposited on the substrate with a target material comprising Al-RE alloy or Al—Ni-RE alloy by a DC magnetron sputtering method.

Preferably, the electrode film deposited on the substrate may be subject to annealing at a temperature of about 150 to about 400° C. after forming the electrode film.

As compared with the related art, the embodiments of the present invention reduce the cost for manufacturing the target material and the electrode film, by substituting Nd which is rare and expensive with RE which is relatively abundant and cheap. According to the present invention, the resistance of the target material and the electrode film to corrosion and oxidation can also be further improved by adding Ni into the target material.

Also, the Al alloy electrode film according to the embodiment of the present invention for a semiconductor device is deposited by using a magnetron sputtering method. For an electrode film deposited by magnetron sputtering, the alloying elements can be solid-dissolved therein to provide a solid solution strengthening effect, so that the thermal stability is improved as compared with the Al alloy film fabricated with other methods.

Further, in the Al alloy manufactured according to the embodiments of the present invention, the alloying elements are all in a solid solution state. The annealing process performed subsequently causes all or part of the alloying elements in the solid solution state to segregate among the crystal grains in a form of intermetallic compound, so that the resistivity of the alloy film can be reduced. Thus, the alloy film can satisfy the requirement of low resistivity and high thermal stability by applying a heat treatment after the deposition of the alloy film.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIG. 1 illustrates variation of resistivity of an alloy film according to an embodiment with respect to different annealing temperatures, for different contents of RE in an Al-RE alloy;

FIG. 2 illustrates variation of resistivity of an alloy film according to an embodiment with respect to different annealing temperatures, for different contents of RE in an Al—Ni-RE alloy;

FIG. 3 illustrates variation of hillock density of an alloy film according to an embodiment with respect to different contents of RE in an Al-RE alloy, at an annealing temperature of 400° C.; and

FIG. 4 illustrates variation of hillock density of an alloy film according to an embodiment with respect to different contents of RE in an Al—Ni-RE alloy, at an annealing temperature of 400° C.

### DETAILED DESCRIPTION OF THE PREFERRED EMBODIMENTS

An embodiment of the present invention provides a new target material for manufacturing an electrode film, in which a mixture of rare earth elements RE (RE=La, Ce, Pr, Nd), from which pure Nd is purified, is used to substitute for Nd, so as to obtain an Al alloy at a low cost. Also, metal Ni may be added into the Al alloy to further improve resistance to corrosion and oxidation of the alloy. That is, a suitable alloy of Al-RE or Al—Ni-RE is provided instead of AlNd to form a target material of Al alloy and thereby reduce the manufacturing cost of the target material and the electrode film. In the Al-RE or Al—Ni-RE alloy of the present invention, the content of the alloying element(s) except for Al, i.e., the content of RE in the Al-RE alloy or of RE and Ni in the Al—Ni-RE alloy, is in a range of about 1 at % to about 10 at %, or in a range of about 0.1 wt % to about 20 wt %.

An embodiment of the present invention also provides a method of manufacturing a new target material used for manufacturing an electrode film. A material, which comprises Al and RE and is mixed sufficiently, is heated, for example, by using an induction furnace or a resistance furnace. After the material is totally molten, the molten material is atomized into droplets by ejecting working gas (typically Ar or N₂ gas) with an atomizing nozzle, and the droplets are brought by the flow of the working gas to move quickly toward a cold substrate that is rotating at a speed, so as to form a blank of a density (typically about 95% of the theoretical density) on the surface of the substrate. The blank is preliminarily reshaped, then is densitified for example by thermal isostatic pressing, and finally formed into a final dimension by forging and machining. According to another amendment of the present invention, the material may further comprise Ni, so as to improve the resistance of the resulting target material to corrosion and oxidation. Thus, the initial material may further comprise Ni to finally obtain a shaped blank of Al—Ni-RE alloy.

An embodiment of the present invention provides another method of manufacturing a new target material used for manufacturing film. A material, which comprises Al and RE and is mixed sufficiently, is heated, for example, by using an induction furnace or a resistance furnace. After it is totally molten, the liquid state alloy is blended uniformly and filled or poured into a mold cavity (e.g., a metallic mold or a sand mold), which is preheated to a certain temperature, and then the alloy is left to be cooled to the room temperature. Next, the solidified alloy is taken out of the mold cavity and machined into a final dimension for example with forging. According to another amendment of the present invention, the material may further comprise Ni so as to improve the resistance of the resulting target material to corrosion and oxidation. Thus, the initial material may further comprise Ni to finally obtain a shaped blank of Al—Ni-RE alloy.

It should be noted that, the above mentioned material for manufacturing a target material can be in various forms, as long as it comprises Al, RE and/or Ni in a certain content. For example, mixed powders of Al and RE or of Al, RE and Ni can be used. Alternatively, the material can be Al-RE alloy, Al—Ni-RE alloy or any combination thereof. In addition, Al—Ni alloy can be mixed with Al-RE alloy and/or Al—Ni-RE alloy, so as to obtain the target material.

The method of manufacturing an electrode film according to an embodiment of the present invention is to deposit the electrode film on a substrate or other medium by DC magnetron sputtering a target material of Al-RE or Al—Ni-RE alloy.

As necessary, the method of manufacturing an electrode film of the present invention may be modified to deposit a layer of refractory metal on the substrate or other medium first, and then deposit a layer of Al-RE or Al—Ni-RE as a conductive layer by DC magnetron sputtering a target material of Al-RE or Al—Ni-RE alloy, so as to form a two-layered electrode film. Alternatively, the method may be modified to deposit a layer of refractory metal on the substrate or other medium first, then deposit a layer of Al-RE or Al—Ni-RE as a conductive layer by DC magnetron sputtering a target material of Al-RE or Al—Ni-RE alloy, and then deposit another layer of refractory metal on the conductive film, so as to form a three-layered electrode film.

In order to achieve an electrode film of good characteristics, the electrode film deposited on the substrate or other medium is subject to annealing at a temperature of about 150 to about 450° C. after the above step of forming the electrode film, so as to sediment the alloying element in the form of intermetallic compound, thereby suppressing occurrence of hillocks.

The Al alloy electrode used for a semiconductor device is deposited by using a magnetron sputtering method as discussed above in the embodiment of the present invention. For a film deposited by DC magnetron sputtering, the alloying elements can be solid-dissolved therein to provide a solid solution strengthening effect, so that the thermal stability is improved as compared with Al alloy film fabricated with other conventional methods.

In the Al alloy manufactured according to the embodiment of the present invention, the alloying elements are all in a solid solution state. The annealing process performed subsequently causes all or part of the alloying elements in the solid solution state to segregate among the crystal grains in a form of intermetallic compound, so that the resistivity of the alloy electrode film can be reduced. Thus, the alloy electrode film can satisfy the requirement of low resistivity and high thermal stability by applying a heat treatment after the deposition of the alloy electrode film.

The electrode film according to the embodiment of the present invention can be used for the interconnection wires of a semiconductor device such as an IC, or the gate, source and drain electrodes of a TFT. The electrode film according to the embodiment of the present invention has low resistivity and excellent anti-hillock property, and thus can satisfy the requirement of a semiconductor device. Also, the Nd resource which decreases day by day is saved, and the cost of the target material for depositing electrode film, manufacturing electrode film using this target material, or forming wires for various semiconductor devices using such electrode film can be reduced.

The present invention will be described in further details below with reference to the embodiments thereof.

### Embodiment 1

Powders of Al, Ni and RE with a purity of 99.99 wt % are sufficiently mixed, and then heated by an induction furnace or a resistance furnace. After the material is completely molten, the molten alloy is atomized into droplets by ejecting working gas (typically Ar or N₂ gas) with an atomizing nozzle, and is brought by a flow of the working gas to move quickly toward a cold substrate that is rotating at a certain speed, so as to form a blank of a certain density (typically about 95% of the theoretical density) on a surface of the substrate. The blank is preliminarily reshaped, thermal isostatic pressing densitified, and then formed into a final dimension for a target material through forging and machining.

### Embodiment 2

Powders of Al, Ni and RE, which are sufficiently mixed, are heated by an induction furnace or a resistance furnace. After the material is totally molten, the liquid state alloy is blended uniformly and then poured into a mold cavity (e.g., a metallic mold or sand mold) preheated to a certain temperature, and left to be cooled to the room temperature. Then the solidified alloy is taken out of the mold cavity and machined into the final dimension for a target material with or without forging.

### Embodiment 3

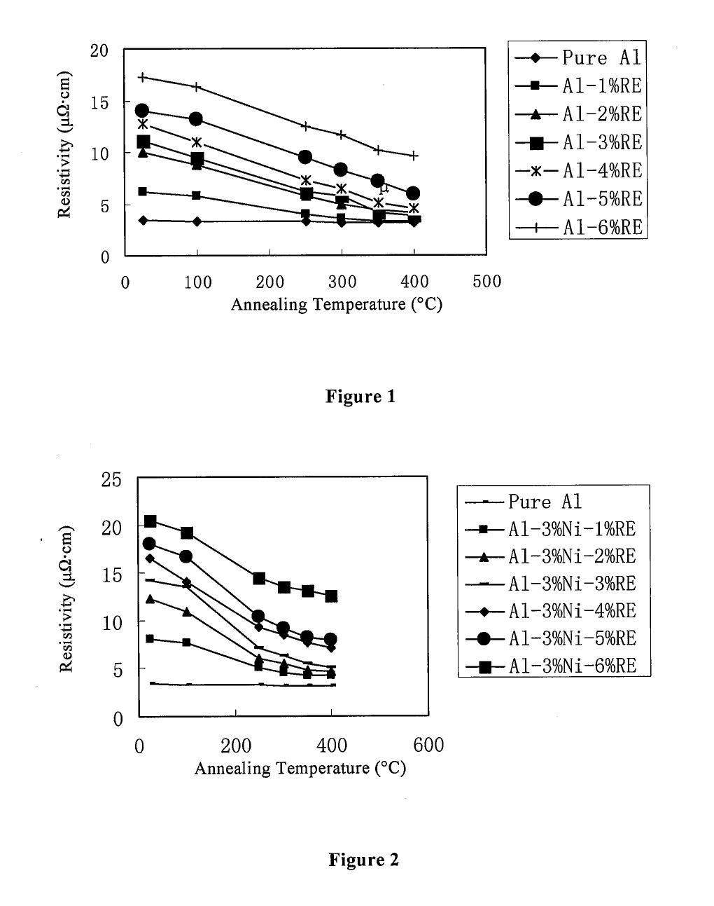

On a glass plate with a thickness of 0.5 mm, an Al alloy film is deposited to a thickness of about 400 nm by DC magnetron sputtering a target material of Al-RE or Al—Ni-RE alloy. The content of the alloying element(s) except Al in the target material is controlled to be about 1 at %-6 at % during manufacturing the target material. The resulting film is cooled to the room temperature after it is annealed at a temperature of 100° C., 200° C., 300° C. or 400° C., and measurement of the resistivity is performed on the films annealed at the different temperatures by using a four-point method. The hillock density of the resulting film is also measured. The content of every component of the film is measured by using Inductive Couple Plasma (ICP) method. The test results are shown in FIGS. 1 to 4.

FIG. 1 illustrates variation of resistivity of the alloy film with respect to different annealing temperatures, for different contents of RE in an Al-RE alloy. With an annealing duration of 0.5 hour, it can be seen that the resistivity increases as the content of RE increases.

FIG. 2 illustrates variation of resistivity of the alloy film with respect to different annealing temperatures, for different contents of RE in an Al—Ni-RE alloy. With an annealing duration of 0.5 hour, it can be seen that the resistivity increases as the content of RE increases, and also the resistivity increases when Ni is added.

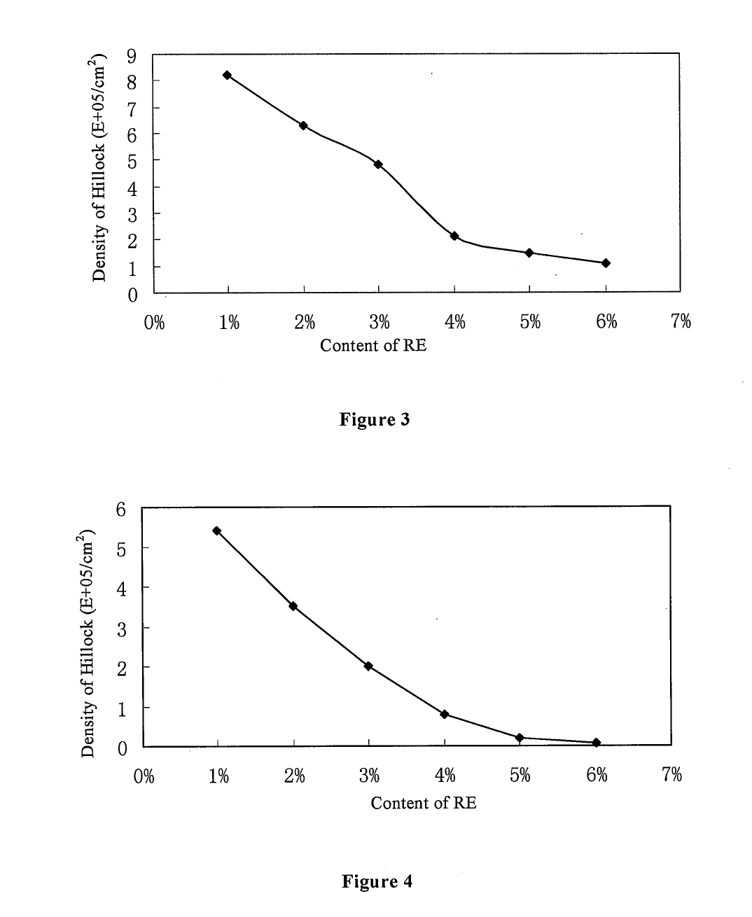

FIG. 3 illustrates variation of hillock density of the alloy film with respect to different contents of RE in an Al-RE alloy, at an annealing temperature of 400° C. With an annealing duration of 0.5 hour, the hillock density decreases as the content of RE increases.

FIG. 4 illustrates variation of hillock density of the alloy film with respect to different contents of RE in an Al—Ni-RE alloy, at an annealing temperature of 400° C. With an annealing duration of 0.5 hour, the hillock density decreases as the content of RE increases, and the addition of Ni can suppress the occurrence of the hillocks.

As shown in the above figures, the resistivity increases with the increment of the contents of alloying elements RE and/or Ni, while the hillock density decreases as the contents of these elements increase. By an annealing at 400° C., the resistivity of the alloy films all drop to a level below 15 μΩcm.

### Embodiment 4

To form a gate electrode of a TFT, a two-layered structure can be formed by first depositing a layer of refractory metal such as Mo, Cr, W or the like on a glass plate by magnetron sputtering, and then depositing a layer of Al-RE or Al—Ni-RE as a conductive layer instead of AlNd alloy. Alternatively, a three-layered structure can be formed by first depositing a layer of refractory metal such as Mo, Cr, W or the like on a glass plate by magnetron sputtering, then depositing a layer of Al-RE or Al—Ni-RE as a conductive layer instead of AlNd alloy, and depositing another layer of refractory metal on the conductive film of Al alloy. A gate line or gate electrode is finally obtained by a photolithography method.

The invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

What is claimed is:

1. A target material for manufacturing an electrode film in a semiconductor device, comprising Al-RE alloy or Al—Ni-RE alloy, wherein RE is a mixture of rare earth elements comprising La, Ce, Pr, and Nd.

2. The target material of claim 1, wherein the target material has a content of about 0.1 wt % to about 20 wt % of RE in Al-RE alloy or of Ni and RE in Al—Ni-RE alloy.

3. A method of manufacturing a target material for an electrode film of a semiconductor device, comprising the steps of:
providing a rotating substrate;
melting a material which comprises Al and RE, wherein RE is a mixture of rare earth elements comprising La, Ce, Pr, and Nd;
atomizing the molten material into droplets by ejecting working gas with an atomizing nozzle;
bringing the droplets with a flow of the working gas to the rotating substrate, so as to form a blank on a surface of the rotating substrate;
performing reshaping and densifying on the blank; and
forming the blank into a final dimension.

4. The method of claim 3, wherein said material comprises powders of Al and RE.

5. The method of claim 3, wherein said material comprises Al-RE alloy.

6. The method of claim 3, wherein said material further comprises Ni.

7. The method of claim 6, wherein said material comprises powders of Al, Ni and RE.

8. The method of claim 6, wherein said material comprises Al—Ni-RE alloy.

9. A method of manufacturing a target material for an electrode film of a semiconductor device, comprising steps of:
melting a material which comprises Al and RE, wherein RE is a mixture of rare earth elements comprising La, Ce, Pr, and Nd;
pouring the molten material into a preheated mold cavity, so as to obtain a blank after the molten material is cooled;
taking the blank out of the mold cavity; and
forming the blank into a final dimension.

10. The method of claim 9, wherein said material comprises powders of Al and RE.

11. The method of claim 9, wherein said material comprises Al-RE alloy.

12. The method of claim 9, wherein said material further comprises Ni.

13. The method of claim 12, wherein said material comprises powders of Al, Ni and RE.

14. The method of claim 12, wherein said material comprises Al—Ni-RE alloy.

15. The method of claim 9, wherein forming the blank into a final dimension is preceded by forging the blank.

16. A method of manufacturing an electrode film of a semiconductor device, comprising:
depositing an electrode film on a substrate with a target material comprising Al-RE alloy or Al—Ni-RE alloy, wherein RE is a mixture of rare earth elements comprising La, Ce, Pr, and Nd.

17. The method of claim 16, further comprising a step of depositing a refractory metal layer on the substrate before the deposition of the electrode film.

18. The method of claim 17, further comprising a step of depositing another layer of refractory metal after the deposition of the electrode film.

19. The method of claim 16, wherein the electrode film deposited on the substrate is subject to annealing at a temperature ranging from about 150 to about 400° C. after the formation of the electrode film.

20. The method of claim 16, wherein the electrode film is deposited on the substrate with the target material by a DC magnetron sputtering method.
